(19) United States
(12) Patent Application Publication
(10) Pub. No.: US 2020/0194625 A1
(43) Pub. Date: Jun. 18, 2020

(54) MN4+-ACTIVATED LUMINESCENT MATERIAL AS CONVERSION PHOSPHOR FOR LED SOLID-STATE LIGHT SOURCES

(71) Applicant: Merck Patent GmbH, Darmstadt (DE)

(72) Inventors: Ralf PETRY, Griesheim (DE); Ingo KOEHLER, Darmstadt (DE); Mathias RAPPHAHN, Greifswald (DE); Thomas JUESTEL, Witten (DE); Thomas JANSEN, Muenster (DE)

(73) Assignee: Merck Patent GmbH, Darmstadt (DE)

(21) Appl. No.: 16/341,105

(22) PCT Filed: Oct. 9, 2017
(86) PCT No.: PCT/EP2017/075579

§ 371 Date: Apr. 11, 2019

(30) Foreign Application Priority Data
Oct. 12, 2016 (EP) 16193525.9

(51) Int. Cl. H01L 33/32; C09K 11/74; H01L 33/50

(52) U.S. Cl. CPC H01L 33/32; H01L 33/502; C09K 11/7435

(57) ABSTRACT

The present invention relates to Mn⁴⁺-activated luminescent materials, to a process for the preparation thereof, and the use thereof as phosphors or conversion phosphors in light sources. The present invention furthermore relates to an emission-converting material comprising the luminescent material according to the invention, and to a light source which comprises the luminescent material according to the invention or the omission-converting material. The present invention furthermore relates to light sources, in particular LEDs, and lighting units which contain a primary light source and the luminescent material according to the invention or the emission-converting material. The Mn⁴⁺-activated luminescent materials according to the invention are suitable, in particular, for the generation of warm-white light in LEDs.

### SUBJECT-MATTER OF THE INVENTION

The present invention relates to Mn⁴⁺-activated luminescent materials, to a process for the preparation thereof, and to the use thereof as phosphors or conversion phosphors, in particular in phosphor-converted light-emitting devices, such as pc-LEDs (phosphor-converted light-emitting diodes). The present invention furthermore relates to an emission-converting material comprising the luminescent material according to the invention, and to a light source which comprises the luminescent material according to the invention or the emission-converting material. The present invention furthermore relates to a lighting unit which contains a light source comprising the luminescent material according to the invention or the emission-converting material according to the invention. The Mn⁴⁺-activated luminescent materials according to the invention are suitable, in particular, for the generation of warm-white light in solid-state LED light sources.

### BACKGROUND OF THE INVENTION

For more than 100 years, inorganic phosphors have been developed in order to adapt the spectra of emitting display screens, X-ray amplifiers and radiation or light sources in such a way that they meet the requirements of the respective area of application in as optimal a manner as possible and at the same time consume as little energy as possible. The type of excitation, i.e. the nature of the primary radiation source, and the requisite emission spectrum are of crucial importance here for the choice of host lattice and the activators.

In particular for fluorescent light sources for general lighting, i.e. low-pressure discharge lamps and light-emitting diodes, novel phosphors are constantly being developed in order further to increase the energy efficiency, colour reproduction and stability.

There are in principle three different approaches to obtaining white-emitting inorganic LEDs (light emitting diodes) by additive colour mixing:
(1) RGB LEDs (red+green+blue LEDs), in which white light is generated by mixing the light from three different light-emitting diodes which emit in the red, green and blue spectral region.
(2) UV LED+RGB phosphor systems, in which a semiconductor which emits in the UV region (primary light source) emits the light to the surrounding area, in which three different phosphors (conversion phosphors) are stimulated to emit in the red, green and blue spectral region. Alternatively, it is possible to use two different phosphors which emit yellow or orange and blue.
(3) Complementary systems, in which an emitting semiconductor (primary light source) emits, for example, blue light, which stimulates one or more phosphors (conversion phosphors) to emit light, for example in the yellow region. By mixing the blue and yellow light, white light is then produced. Alternatively, it is possible to use two or more phosphors which emit, for example, green or yellow and orange or red light.

If a blue-emitting semiconductor is used as primary light source, binary complementary systems require a yellow conversion phosphor in order to reproduce white light. Alternatively, it is possible to use green- and red-emitting conversion phosphors. If, as an alternative, the primary light source used is a semiconductor which emits in the violet spectral region or in the near-UV spectrum, either an RGB phosphor mixture or a dichromatic mixture of two conversion phosphors which emit complementary light must be used in order to obtain white light. On use of a system having a primary light source in the violet or UV region and two complementary conversion phosphors, light-emitting diodes having a particularly high lumen equivalent can be provided. A further advantage of a dichromatic phosphor mixture is the lower spectral interaction and the associated higher package gain.

In particular, inorganic luminescent materials which can be excited in the ultraviolet and/or blue spectral region are therefore gaining ever-greater importance today as conversion phosphors for light sources, in particular for pc-LEDs for the generation of warm-white light.

There is therefore a constant need for novel luminescent materials as conversion phosphors which can be excited in the ultraviolet or blue spectral region and emit light in the visible region, in particular in the red spectral region. The primary aims are therefore expansion of the product range, improvement in the colour reproduction of white LEDs and achievement of trichromatic LEDs. To this end, it is necessary to provide green-, yellow- and red-emitting phosphors having high absorption in the blue, violet or UV spectral region, a high quantum yield and a high lumen equivalent.

Mn⁴⁺-activated luminescent materials are used in fluorescent light sources (CFLs, TLs, LEDs) and in emissive display screens (cathode ray tubes) for the conversion of non-visible radiation or high-energy particles into visible light. A material which is quite widely used for this purpose is Mg₈Ge₂O₁₁F₂:Mn, whose emission maximum is at about 660 nm and which can be excited readily at 160 nm or 254 nm, but also in the deep-blue spectral region. It is therefore also of limited suitability for use in phosphor-converted LEDs, especially as Mn⁴⁺-doped phosphors can also exhibit efficient photoluminescence at high temperatures (100-200° C.).

A disadvantage of the use of Mn⁴⁺-activated phosphors in high-performance solid-state LED light sources is the usually relatively low absorption cross section in the near UV or blue spectral region. This finding greatly restricts the economic use of Mn⁴⁺-activated phosphors as radiation converters in near-UV or blue LEDs. In addition, LEDs having high colour reproduction at the same time as a high lumen yield require a red phosphor having an emission maximum in the red spectral region from 620 to 640 nm, which is only possible to a limited extent in oxidic host materials.

For this reason, the search for novel Mn⁴⁺-activated phosphors for LEDs continues to be pursued vigorously in many academic and industrial research laboratories, for example at General Electric.

Thus, WO 2014/152787 A1 discloses a process for the synthesis of colourstable Mn⁴⁺-doped phosphors in which, for example, K₂[SiF₆]:Mn⁴⁺, K₂[TiF₆]:Mn⁴⁺ or K₂[SnF₆]:Mn⁴⁺ as precursors in gas form are reacted with a fluorine-containing oxidant at elevated temperature.

WO 2014/179000 A1 describes a process for the production of a light-emitting device which comprises a light-emitting diode (LED) and a coated phosphor composite material. The phosphor composite material contains a first phosphor layer comprising a yellow-emitting phosphor, which is arranged above a second phosphor layer comprising a manganese-doped potassium fluorosilicate (PFS). WO 2014/179000 A1 discloses red-emitting Mn⁴⁺-doped complex fluoride phosphors, such as, for example, K₂[SiF₆]:Mn⁴⁺, K₂[TiF₆]:Mn⁴⁺ and K₂[SnF₆]:Mn⁴⁺.

WO 2008/100517 A1 relates to light-emitting devices having a light source and a phosphor material, where the phosphor material comprises a complex Mn⁴⁺-activated fluoride phosphor which includes at least one of the following compounds: (A) A₂[MF₅]:Mn⁴⁺, (B) A₃[MF₆]:Mn⁴⁺, (C) Zn₂[MF₇]:Mn⁴⁺ or (D) A[In₂F₇]:Mn⁴⁺ where A=Li, Na, K, Rb, Cs and/or NH₄ and M=Al, Ga and/or In.

The luminescent materials known from the prior art are usually obtained by reaction of a precursor compound with a fluorine-containing oxidant in the gas phase at elevated temperature or in the aqueous phase. The use of highly corrosive fluorine-containing oxidants of this type makes high technical demands of the reaction vessel and its material. This makes the synthesis complex and expensive.

A further disadvantage of the Mn⁴⁺-doped fluorides known to date is their low stability, in particular on irradiation with blue light or UV radiation, when the fluorides partially liberate fluorine, causing flaws to remain in the material itself and causing the reduction of Mn⁴⁺. This impairs the service life and the stability of the colour temperature.

### OBJECT OF THE INVENTION

An object of the present invention is to provide luminescent materials with long-term stability which exhibit luminescence in the red spectral region and are suitable, in particular, for use in high-performance pc-LEDs for the generation of warm-white light. This allows the person skilled in the art a greater choice of suitable materials for the production of white-emitting devices.

An object of the present invention is thus to provide novel luminescent materials which are distinguished by a broad absorption cross section in the near UV to blue spectral region, have an emission maximum in the red spectral region between 620 and 640 nm and are thus suitable for use as conversion phosphors in LEDs having high colour reproduction. In addition, an object of the invention is to provide luminescent materials having a long service life which are readily accessible through an efficient and inexpensive synthesis. A further object of the present invention is to improve the colour rendering index and the stability of the colour temperature in an LED. This enables warm-white pc-LEDs having high colour rendering indices at the same time as low colour temperatures (CCT<4000 K) to be achieved.

### DESCRIPTION OF THE INVENTION

Surprisingly, it has been found that the objects of the present invention are achieved by Mn⁴⁺-activated luminescent materials based on a fluoride host lattice of the form M¹M²F₆ (where M¹=Li, Na, K, Rb and/or Cs; M²=As, Sb and/or Bi). The inventors have surprisingly found that red-emitting luminescent materials having emission maxima between 620 and 640 nm, a high quantum yield, high colour reproduction, a long service life and high stability of the colour temperature can be achieved by incorporating Mn⁴⁺ ions into the fluoride host lattice M¹M²F₆ (where M¹=Li, Na, K, Rb and/or Cs; M²=As, Sb and/or Bi), giving luminescent materials of the general composition M¹M²F₆:Mn⁴⁺. In addition, the luminescent materials are accessible efficiently and inexpensively by a simple synthesis, where, in particular, As⁵⁺, Sb⁵⁺ and Bi⁵⁺ are suitable for achieving long-term-stable fluorides, since the associated complex anions [M²F₆]⁻ have extraordinarily high stability.

The tetravalent Mn⁴⁺ ions are incorporated at the lattice sites of the pentavalent M² ions (M²=As, Sb and/or Bi). The doping with Mn⁴⁺ allows a simple and efficient synthesis, since the Mn⁴⁺ ions readily insert themselves into the crystal structure of the host lattice. The charge compensation takes place as a result of fluoride flaws in the host lattice.

Compounds of this general composition are red-emitting Mn⁴⁺ luminescent materials whose emission line multiplet in the red spectral region has a maximum between 620 and 640 nm and which are claimed for use as conversion phosphors in solid-state radiation sources of any type, such as, for example, solid-state LED light sources or high-performance solid-state LED light sources. The CIE1931 colour coordinates of all materials claimed here are at x>0.66 and y<0.33. The lumen equivalent is higher than 200 lm/W.

The present invention thus relates to a compound of the following general formula (I) or (II),

M¹M²₁₋ₓMnₓF₆₋ₓ (I)

where the following applies to the symbols and indices used:
M¹ is selected from the group consisting of Li, Na, K, Rb, Cs and mixtures of two, three or more thereof;
M² is selected from the group consisting of As, Sb, Bi and mixtures of two or three thereof; and
0<x<1.00.

In the general formula (I) above, M¹ is a singly charged metal atom (M¹)⁺. M² is a quintuply charged metal atom (M²)⁵⁺. Mn is in the form of quadruply charged metal atom Mn⁴⁺, while fluorine is present in the compound in the form of fluoride (F⁻).

The Mn⁴⁺-activated luminescent materials according to the invention are conversion materials which are doped with Mn⁴⁺. In the general formula (I), one Mn⁴⁺ ion replaces one (M²)⁵⁺ ion and one F ion. The charge is thus compensated by fluoride flaws in the host lattice.

The compounds according to the invention can usually be excited in the spectral region from about 250 to about 550 nm, preferably from about 300 to about 525 nm, more preferably from about 300 to about 400 nm or from about 400 to 525 nm, most preferably from about 425 to about 500 nm, and usually emit in the red spectral region from about 600 to about 650 nm, where the emission maximum is in the spectral region between 620 and 640 nm, preferably between 625 and 635 nm. In addition, the compounds according to the invention exhibit a high photoluminescence quantum yield and have high colour reproduction and high stability of the colour temperature on use in an LED.

In the context of this application, UV light denotes light whose emission maximum is between 100 and 389 nm, violet light denotes light whose emission maximum is between 390 and 399 nm, blue light denotes light whose emission maximum is between 400 and 459 nm, cyan-coloured light denotes light whose emission maximum is between 460 and 505 nm, green light denotes light whose emission maximum is between 506 and 545 nm, yellow light denotes light whose emission maximum is between 546 and 565 nm, orange light denotes light whose emission maximum is between 566 and 600 nm and red light denotes light whose emission maximum is between 601 and 750 nm.

In a preferred embodiment of the invention, M¹ is selected from the group consisting of Li, Na, K and mixtures of two or three thereof. In a more preferred embodiment, M¹ is selected from the group consisting of Li, Na and K.

In a preferred embodiment of the invention, M² is selected from the group consisting of As, Sb and mixtures of As and Sb, which may optionally comprise Bi.

In a preferred embodiment of the invention, M² is selected from mixtures consisting of As and Sb, As and Bi, Sb and Bi, as well as As, Sb and Bi.

In a preferred embodiment of the invention, the following applies to the index x in the general formula (I): 0<x≤0.80, preferably 0<x≤0.60, more preferably 0<x≤0.40, particularly preferably 0.001≤x≤0.20, especially preferably 0.001≤x≤0.10 and most preferably 0.001≤x≤0.010.

In a particularly preferred embodiment of the invention, a plurality of the preferred features mentioned above applies simultaneously, irrespective of whether they are preferred, particularly preferred, more preferred and/or most preferred features.

Particular preference is therefore given to compounds of the general formula (I) for which the following applies:
M¹ is selected from the group consisting of Li, Na, K and mixtures of two or three thereof;
M² is selected from the group consisting of As, Sb and mixtures of As and Sb, which may optionally comprise Bi; and
0<x≤0.60, preferably 0<x≤0.40, more preferably 0.001≤x≤0.20, particularly preferably 0.001≤x≤0.10 and most preferably 0.001≤x≤0.010.

The compound according to the invention can preferably be coated on its surface with another compound, as described below.

The present invention furthermore relates to a process for the preparation of a compound of the general formula (I), comprising the following steps:
a) preparation of a suspension/solution containing M¹, M² and Mn in an HF solution;
b) stirring the suspension/solution; and
c) separating off the solid obtained.

The preparation of the suspension/solution in step a) is carried out by suspension/dissolution of salts containing M¹, M², Al and Mn in an HF solution.

The salts can be added in step a) either successively in any desired sequence or simultaneously. The salts can be added either as solids or as suspensions/solutions. The HF solution used is preferably a concentrated HF solution. Concentrated aqueous HF solution (hydrofluoric acid) comprising 10-60% by weight of HF, more preferably 20-50% by weight of HF and most preferably 30-40% by weight of HF, is preferably used in the preparation process according to the invention.

In the process for the preparation of a compound of the general formula (I), the salt employed in step a) as starting compounds for the ions (M¹)⁺ and (M²)⁵⁺ is preferably fluoride compounds, such as, for example, M¹M²F₆, NH₄M²F₆, M¹F and M²F₅. Preferred fluoride compounds M¹M²F₆ are: LiAsF₆, NaAsF₆, KAsF₆, RbAsF₆, CsAsF₆, LiSbF₆, NaSbF₆, KSbF₆, RbSbF₆, CsSbF₆, LiBiF₆, NaBiF₆, KBiF₆, RbBiF₆ and CsBiF₆. Preferred fluoride compounds NH₄M²F₆ are: NH₄AsF₆, NH₄SbF₆ and NH₄BiF₆. Preferred fluoride compounds M¹F are: LiF, NaF, KF, RbF and CsF. Preferred fluoride compounds M²F are: AsF₅, SbF₅ and BiF₅.

In step a), Mn is preferably employed as starting compounds in the form of tetravalent manganese salts, such as, for example, M¹₂MnF₆. Preferred tetravalent manganese salts M¹₂MnF₆ are Li₂MnF₆, Na₂MnF₆, K₂MnF₆, Rb₂MnF₆ and Cs₂MnF₆.

The suspension/dissolution of the starting compounds can be carried out at temperatures between 0 and 100° C., preferably between 20 and 90° C., more preferably between 40 and 80° C. and most preferably between 50 and 75° C.

The stirring of the suspension/solution in step b) is preferably carried out at temperatures between 0 and 100° C., preferably between 20 and 90° C., more preferably between 40 and 80° C. and most preferably between 50 and 75° C. for a time of up to 10 h, preferably up to 6 h, more preferably up to 4 h and most preferably up to 3 h. Preferred times for the stirring of the suspension/solution in step b) are 0.1-10 h, 0.5-6 h, 1-4 h and 2-3 h. In a preferred embodiment, the stirring of the suspension/solution in step b) is carried out at a temperature between 50 and 75° C. for 2-3 h.

The separating-off of the solid obtained in step c) is preferably carried out by filtration, centrifugation or decantation, more preferably by filtration via a suction filter.

In a preferred embodiment of the present invention, step c) is followed by a further step d), in which the solid obtained in step c) is washed and dried. The washing of the solid is preferably carried out with an organic solvent until the solid is acid-free. Preference is given to organic aprotic solvents, such as, for example, acetone, hexane, heptane, octane, dimethylformamide (DMF) and dimethyl sulfoxide (DMSO). The solvent used for the washing preferably has a temperature of −10 to 20° C.

The drying of the solid in step d) is preferably carried out under reduced pressure. The drying can be carried out at room temperature (20 to 25° C.) or at an elevated temperature, such as, for example, 25 to 150° C. After the drying in step d), the desired luminescent compound is obtained.

In a further embodiment, the luminescent materials according to the invention may be coated. Suitable for this purpose are all coating methods as are known to the person skilled in the art from the prior art and are used for phosphors. Suitable materials for the coating are, in particular, metal oxides and nitrides, in particular alkaline-earth metal oxides, such as Al₂O₃, and alkaline-earth metal nitrides, such as AlN, as well as SiO₂. The coating can be carried out here, for example, by fluidised-bed methods or by wet-chemical methods. Suitable coating methods are disclosed, for example, in JP 04-304290, WO 91/10715, WO 99/27033, US 2007/0298250, WO 2009/065480 and WO 2010/075908, which are incorporated herein by way of reference. The aim of the coating can on the one hand be higher stability of the luminescent materials, for example to air or moisture. However, the aim may also be improved coupling in and out of light through a suitable choice of the surface of the coating and the refractive indices of the coating material.

The present invention still furthermore relates to the use of the luminescent materials according to the invention as phosphor or conversion phosphor, in particular for the partial or complete conversion of UV light, violet light and/or blue light into light having a longer wavelength.

The compounds according to the invention are therefore also called phosphors.

The present invention furthermore relates to an emission-converting material comprising a compound according to the invention. The emission-converting material may consist of the compound according to the invention and would in this case be equivalent to the term “phosphor” or “conversion phosphor” defined above. It may also be preferred for the emission-converting material according to the invention also to comprise further conversion phosphors besides the compound according to the invention. In this case, the emission-converting material according to the invention preferably comprises a mixture of at least two conversion phosphors, where at least one thereof is a compound according to the invention. It is particularly preferred for the at least two conversion phosphors to be phosphors which emit light having wavelengths which are complementary to one another.

If the compounds according to the invention are employed in small amounts, they already give rise to good LED qualities. The LED quality is described here by means of conventional parameters, such as, for example, the colour rendering index (CRI), the correlated colour temperature (CCT), lumen equivalent or absolute lumen, or the colour point in CIE x and y coordinates.

The colour rendering index (CRI) is a dimensionless lighting quantity, familiar to the person skilled in the art, which compares the colour reproduction faithfulness of an artificial light source with that of sunlight or filament light sources (the latter two have a CRI of 100).

The correlated colour temperature (CCT) is a lighting quantity, familiar to the person skilled in the art, with the unit kelvin. The higher the numerical value, the higher the blue content of the light and the colder the white light from an artificial radiation source appears to the observer. The CCT follows the concept of the black body radiator, whose colour temperature describes the so-called Planck curve in the CIE diagram.

The lumen equivalent is a lighting quantity, familiar to the person skilled in the art, with the unit lm/W which describes the magnitude of the photometric luminous flux in lumens of a light source at a certain radiometric radiation power with the unit watt. The higher the lumen equivalent, the more efficient a light source.

The lumen is a photometric lighting quantity, familiar to the person skilled in the art, which describes the luminous flux of a light source, which is a measure of the total visible radiation emitted by a radiation source. The greater the luminous flux, the brighter the light source appears to the observer.

CIE x and CIE y stand for the coordinates in the standard CIE colour chart (here standard observer 1931), familiar to the person skilled in the art, by means of which the colour of a light source is described.

All the quantities mentioned above can be calculated from the emission spectra of the light source using methods known to the person skilled in the art.

The excitability of the phosphors according to the invention extends over a broad range, which extends from about 250 nm to about 550 nm, preferably from about 300 nm to about 525 nm, more preferably from about 300 to about 400 nm or from about 400 to 525 nm, most preferably from about 425 to about 500 nm.

The present invention furthermore relates to a light source which comprises at least one primary light source and at least one compound according to the invention or an emission-converting material according to the invention.

The emission maximum of the primary light source here is usually in the range from about 250 nm to about 550 nm, preferably from about 300 nm to about 525 nm, more preferably from about 300 to about 400 nm or from about 400 to 525 nm, most preferably about 425 to about 500 nm, where the primary radiation is converted partly or fully into longer-wave radiation by the phosphor according to the invention.

In a preferred embodiment of the light source according to the invention, the primary light source comprises a luminescent indium aluminium gallium nitride compound, which is preferably represented by the formula InᵢGaⱼAlₖN, where 0≤i, 0≤j, 0≤k, and i+j+k=1.

Possible forms of light sources of this type are known to the person skilled in the art. These can be light-emitting LED chips of various structure.

In a further preferred embodiment of the light source according to the invention, the primary light source is a luminescent arrangement based on ZnO, TCO (transparent conducting oxide), ZnSe or SiC or an arrangement based on an organic light-emitting layer (OLED).

In a further preferred embodiment of the light source according to the invention, the primary light source is a source which exhibits electroluminescence and/or photoluminescence. The primary light source may furthermore also be a plasma or discharge source.

Corresponding light sources according to the invention are also known as light-emitting diodes or LEDs.

The luminescent materials according to the invention can be employed individually or as a mixture with suitable phosphors which are familiar to the person skilled in the art. Corresponding phosphors which are in principle suitable for mixtures are, for example: Ba₂SiO₄:Eu²⁺, BaSi₂N₂O₂:Eu, BaSi₂O₅:Pb²⁺, Ba₃Si₆O₁₂N₂:Eu, BaₓSr₁₋ₓF₂:Eu²⁺ (where 0≤x≤1), BaSrMgSi₂O₇:Eu²⁺, BaTiP₂O₇, (Ba,Ti)₂P₂O₇:Ti, BaY₂F₈:Er³⁺, Yb⁺, Be₂SiO₄:Mn²⁺, Bi₄Ge₃O₁₂, CaAl₂O₄:Ce³⁺, CaLa₄O₇:Ce³⁺, CaAl₂O₄:Eu²⁺, CaAl₂O₄:Mn²⁺, CaAl₄O₇:Pb²⁺, Mn²⁺, CaAl₂O₄:Tb³⁺, Ca₃Al₂Si₃O₁₂:Ce³⁺, Ca₃Al₂Si₃O₁₂:Ce³⁺, Ca₃Al₂Si₃O₂:Eu²⁺, Ca₂B₅O₉Br:Eu²⁺, Ca₂B₅O₉Cl:Eu²⁺, Ca₂B₅O₉Cl:Pb²⁺, CaB₂O₄:Mn²⁺, Ca₂B₂O₅:Mn²⁺, CaB₂O₄:Pb²⁺, CaB₂P₂O₉:Eu²⁺, Ca₅B₂SiO₁₀:Eu³⁺, Ca_{0.5}Ba_{0.5}Al₁₂O₁₉:Ce³⁺, Mn²⁺, Ca₂Ba₃(PO₄)₃Cl:Eu²⁺, CaBr₂:Eu²⁺ in SiO₂, CaCl₂:Eu²⁺ in SiO₂, CaCl₂:Eu²⁺, Mn²⁺ in SiO₂, CaF₂:Ce³⁺, CaF₂:Ce³⁺, Mn²⁺, CaF₂:Ce³⁺, Tb³⁺, CaF₂:Eu²⁺, CaF₂:Mn²⁺, CaGa₂O₄:Mn²⁺, CaGa₄O₇:Mn²⁺, CaGa₂S₄:Ce³⁺, CaGa₂S₄:Eu²⁺, CaGa₂S₄:Mn²⁺, CaGa₂S₄:Pb²⁺, CaGeO₃:Mn²⁺, CaI₂:Eu²⁺ in SiO₂, CaI₂:Eu²⁺, Mn²⁺ in SiO₂, CaLaBO₄:Eu³⁺, CaLaB₃O₇:Ce³⁺, Mn²⁺, Ca₂La₂BO_{6.5}:Pb²⁺, Ca₂MgSi₂O₇, Ca₂MgSi₂O₇:Ce³⁺, CaMgSi₂O₆:Eu²⁺, Ca₃MgSi₂O₈:Eu²⁺, Ca₂MgSi₂O₇:Eu²⁺, CaMgSi₂O₆:Eu²⁺, Mn²⁺, Ca₂MgSi₂O₇:Eu²⁺, Mn²⁺, CaMoO₄, CaMoO₄:Eu³⁺, CaO:Bi³⁺, CaO:Cd²⁺, CaO:Cu⁺, CaO:Eu³⁺, CaO:Eu³⁺, Na⁺, CaO:Mn²⁺, CaO:Pb²⁺, CaO:Sb³⁺, CaO:Sm³⁺, CaO:Tb³⁺, CaO:Tl, CaO:Zn²⁺, Ca₂P₂O₇:Ce³⁺, α-Ca₃(PO₄)₂:Ce³⁺, β-Ca₃(PO₄)₂:Ce³⁺, Ca₅(PO₄)₃Cl:Eu²⁺, Ca₅(PO₄)₃Cl:Mn²⁺, Ca₅(PO₄)₃Cl:Sb³⁺, Ca₅(PO₄)₃Cl:Sn²⁺, β-Ca₃(PO₄)₂:Eu²⁺, Mn²⁺, Ca₅(PO₄)₃F:Mn²⁺, Ca₅(PO₄)₃F:Sb³⁺, Ca₅(PO₄)₃F:Sn²⁺, α-Ca₃(PO₄)₂:Eu²⁺, β-Ca₃(PO₄)₂:Eu²⁺, Ca₂P₂O₇:Eu²⁺, Ca₂P₂O₇:Eu²⁺, Mn²⁺, CaP₂O₆:Mn²⁺, α-Ca₃(PO₄)₂:Sn²⁺, β-Ca₃(PO₄)₂:Sn²⁺, β-Ca₂P₂O₇:Sn, Mn, α-Ca₃(PO₄)₂:Tr, CaS:Bi³⁺, CaS:Bi³⁺, Na, CaS:Ce³⁺, CaS:Eu²⁺, CaS:Cu⁺, Na⁺, CaS:La³⁺, CaS:Mn²⁺, CaSO₄:Bi, CaSO₄:Ce³⁺, CaSO₄:Ce³⁺, Mn²⁺, CaSO₄:Eu²⁺, CaSO₄:Eu²⁺, Mn²⁺, CaSO₄:Pb²⁺, CaS:Pb²⁺, CaS:Pb²⁺, Cl, CaS:Pb², Mn²⁺, CaS:Pr³⁺, Pb²⁺, Cl, CaS:Sb³⁺, CaS:Sb³⁺, Na, CaS:Sm³⁺, CaS:Sn²⁺, CaS:Sn²⁺, F, CaS:Tb³⁺, CaS:Tb³⁺, Cl, CaS:Y³⁺, CaS:Yb²⁺, CaS:Yb²⁺, Cl, CaSc₂O₄:Ce, Ca₃(Sc,Mg)₂Si₃O₁₂:Ce, CaSiO₃:Ce³⁺, Ca₃SiO₄Cl₂:Eu²⁺, Ca₃SiO₄Cl₂:Pb²⁺, CaSiO₃:Eu²⁺, CaSiO₃:Mn²⁺, Pb, CaSiO₃:Pb²⁺, CaSiO₃:Pb²⁺, Mn²⁺, CaSiO₃:Ti⁴⁺, CaSr₂(PO₄)₂:Bi³⁺, β-(Ca,Sr)₃(PO₄)₂:Sn²⁺, Mn²⁺, CaTi_{0.9}Al_{0.1}O₃:Bi³⁺, CaTiO₃:Eu³⁺, CaTiO₃:Pr³⁺, Ca₅(VO₄)₃Cl, CaWO₄, CaWO₄:Pb²⁺, CaWO₄:W, Ca₃WO₆:U, CaYAlO₄:Eu³⁺, CaYBO₄:Bi³⁺, CaYBO₄:Eu³⁺, CaYB_{0.8}O_{3.7}:Eu³⁺, CaY₂ZrO₆:Eu³⁺, (Ca,Zn,Mg)₃(PO₄)₂:Sn, (Ce,Mg)BaAl₁₁O₁₈:Ce, (Ce,Mg)SrAl₁₁O₁₈:Ce, CeMgAl₁₁O₁₉:Ce:Tb, Cd₂B₆O₁₁:Mn²⁺, CdS:Ag⁺, Cr, CdS:In, CdS:In, CdS:In, Te, CdS:Te, CdWO₄, CsF, CsI, CsI:Na⁺, CsI:Tl, (ErCl₃)_{0.25}(BaCl₂)_{0.75}, GaN:Zn, Gd₃Ga₅O₁₂:Cr³⁺, Gd₃Ga₅O₁₂:Cr, Ce, GdNbO₄:Bi³⁺, Gd₂O₂S:Eu³⁺, Gd₂O₂Pr³⁺, Gd₂O₂S:Pr, Ce, F, Gd₂O₂S:Tb³⁺, Gd₂SiO₅:Ce³⁺, KAl₁₁O₁₇:Tl⁺, KGa₁₁O₁₇:Mn²⁺, K₂La₂Ti₃O₁₀:Eu, KMgF₃:Eu²⁺, KMgF₃:Mn²⁺, K₂SiF₆:Mn⁴⁺, LaAl₃B₄O₁₂:Eu³⁺, LaAlB₂O₆:Eu³⁺, LaAlO₃:Eu³⁺, LaAlO₃:Sm³⁺, LaAsO₄:Eu³⁺, LaBr₃:Ce³⁺, LaBO₃:Eu³⁺, LaCl₃:Ce³⁺, La₂O₃:Bi³⁺, LaOBr:Tb³⁺, LaOBr:Tm³⁺, LaOCl:Bi³⁺, LaOCl:Eu³⁺, LaOF:Eu³⁺, La₂O₃:Eu³⁺, La₂O₃:Pr³⁺, La₂O₂S:Tb³⁺, LaPO₄:Ce³⁺, LaPO₄:Eu³⁺, LaSiO₃Cl:Ce³⁺, LaSiO₃Cl:Ce³⁺, Tb³⁺, LaVO₄:Eu³⁺, La₂W₃O₁₂:Eu³⁺, LiAlF₄:Mn²⁺, LiAl₅O₈:Fe³⁺, LiAlO₂:Fe³⁺, LiAlO₂:Mn²⁺, LiAl₅O₈:Mn²⁺, Li₂CaP₂O₇:Ce³⁺, Mn²⁺, LiCeBa₄Si₄O₁₄:Mn²⁺, LiCeSrBa₃Si₄O₁₄:Mn²⁺, LiInO₂:Eu³⁺, LiInO₂:Sm³⁺, LiLaO₂:Eu³⁺, LuAlO₃:Ce³⁺, (Lu,Gd)₂SiO₅:Ce³⁺, Lu₂SiO₅:Ce³⁺, Lu₂Si₂O₇:Ce³⁺, LuTaO₄:Nb⁵⁺, Lu₁₋ₓYₓAlO₃:Ce³⁺ (where 0≤x≤1), (Lu,Y)₃(Al,Ga,Sc)₅O₁₂:Ce, MgAl₂O₄:Mn²⁺, MgSrAl₁₀O₁₇:Ce, MgB₂O₄:Mn²⁺, MgBa₂(PO₄)₂:Sn²⁺, MgBa₂(PO₄)₂:U, MgBaP₂O₇:Eu²⁺, MgBaP₂O₇:Eu²⁺, Mn²⁺, MgBa₃Si₂O₈:Eu²⁺, MgBa(SO₄)₂:Eu²⁺, Mg₃Ca₃(PO₄)₄:Eu²⁺, MgCaP₂O₇:Mn²⁺, Mg₂Ca(SO₄)₃:Eu²⁺, Mg₂Ca(SO₄)₃:Eu²⁺, Mn², MgCeAl, O₁₉:Tb³⁺, Mg₄(F)GeO₆:Mn²⁺, Mg₄(F)(Ge,Sn)O₆:Mn²⁺, MgF₂:Mn²⁺, MgGa₂O₄:Mn²⁺, Mg₈Ge₂ O₁₁F₂:Mn⁴⁺, MgS:Eu²⁺, MgSiO₃:Mn²⁺, Mg₂SiO₄:Mn²⁺, Mg₃SiO₃F₄:Ti⁴⁺, MgSO₄:Eu²⁺, MgSO₄:Pb²⁺, MgSrBa₂Si₂O₇:Eu²⁺, MgSrP₂O₇:Eu²⁺, MgSr₅(PO₄)₄:Sn²⁺, MgSr₃Si₂O₈:Eu²⁺, Mn²⁺, Mg₂Sr(SO₄)₃:Eu²⁺, Mg₂TiO₄:Mn⁴⁺, MgWO₄, MgYBO₄:Eu³⁺, Na₃Ce(PO₄)₂:Tb³⁺, Na_{1.23}K_{0.42}Eu_{0.12}TiSi₄O₁₁:Eu³⁺, Na_{1.23}K_{0.42}Eu_{0.12}TiSi₅O₁₃.xH₂O:Eu³⁺, Na_{1.29}K_{0.46}Er_{0.08}TiSi₄O₁₁:Eu³⁺, Na₂Mg₃Al₂Si₂O₁₀:Tb, Na(Mg₂₋ₓMnₓ)LiSi₄O₁₀F₂:Mn (where 0≤x≤2), NaYF₄:Er³⁺, Yb³⁺, NaYO₂:Eu³⁺, P46(70%)+P47 (30%), β-SiAlON:Eu, SrAl₁₂O₁₉:Ce³⁺, Mn²⁺, SrAl₂O₄:Eu²⁺, SrAl₄O₇:Eu³⁺, SrAl₁₂O₁₉:Eu²⁺, SrAl₂S₄:Eu²⁺, Sr₂B₅O₉Cl:Eu²⁺, SrB₄O₇:Eu²⁺(F,Cl,Br), SrB₄O₇:Pb²⁺, SrB₄O₇:Pb²⁺, Mn²⁺, SrB₈O₁₃:Sm²⁺, SrₓBa_{y}Cl_{z}Al₂O_{4-z/2}:Mn²⁺, Ce³⁺, SrBaSiO₄:Eu²⁺, (Sr,Ba)₃SiO₅:Eu, (Sr,Ca)Si₂N₂O₂:Eu, Sr(Cl,Br,I)₂:Eu²⁺, in SiO₂, SrCl₂:Eu²⁺ in SiO₂, Sr₅Cl(PO₄)₃:Eu, Sr_{w}FₓB₄O_{6.5}:Eu²⁺, Sr_{w}FₓB_{y}O_{z}:Eu²⁺, Sm²⁺, SrF₂:Eu²⁺, SrGa₁₂O₁₉:Mn²⁺, SrGa₂S₄:Ce³⁺, SrGa₂S₄:Eu²⁺, SrGa₂S₄:Pb²⁺, SrIn₂O₄:Pr³⁺, Al³⁺, (Sr,Mg)₃(PO₄)₂:Sn, SrMgSi₂O₆:Eu²⁺, Sr₂MgSi₂O₇:Eu²⁺, Sr₃MgSi₂O₈:Eu²⁺, SrMoO₄:U, SrO.3B₂O₃:Eu²⁺, Cl, β-SrO.3B₂O₃:Pb²⁺, β-SrO.3B₂O₃:Pb²⁺, Mn²⁺, α-SrO.3B₂O₃:Sm²⁺, Sr₆P₅BO₂₀:Eu, Sr₅(PO₄)₃Cl:Eu²⁺, Sr₅(PO₄)₃Cl:Eu²⁺, Pr³⁺, Sr₅(PO₄)₃Cl:Mn²⁺, Sr₅(PO₄)₃Cl:Sb³⁺, Sr₂P₂O₇:Eu²⁺, β-Sr₃(PO₄)₂:Eu²⁺, Sr₅(PO₄)₃F:Mn²⁺, Sr₅(PO₄)₃F:Sb³⁺, Sr₅(PO₄)₃F:Sb³⁺, Mn²⁺, Sr₅(PO₄)₃F:Sn²⁺, Sr₂P₂O₇:Sn²⁺, β-Sr₃(PO₄)₂:Sn²⁺, β-Sr₃(PO₄)₂:Sn²⁺, Mn²⁺(Al), SrS:Ce³⁺, SrS:Eu²⁺, SrS:Mn²⁺, SrS:Cu⁺, Na, SrSO₄:Bi, SrSO₄:Ce³⁺, SrSO₄:Eu²⁺, SrSO₄:Eu²⁺, Mn²⁺, Sr₅Si₄O₁₀Cl₆:Eu²⁺, Sr₂SiO₄:Eu²⁺, SrTiO₃:Pr³⁺, SrTiO₃:Pr³⁺, Al³⁺, SrY₂O₃:Eu³⁺, ThO₂:Eu³⁺, ThO₂:Pr³⁺, ThO₂:Tb³⁺, YAl₃B₄O₁₂:Bi³⁺, YAl₃B₄O₁₂:Ce³⁺, YAl₃B₄O₁₂:Ce³⁺, Mn, YAl₃B₄O₁₂:Ce³⁺, Tb³⁺, YAl₃B₄O₁₂:Eu³⁺, YAl₃B₄O₁₂:Eu³⁺, Cr³⁺, YAl₃B₄O₁₂:Th⁴⁺, Ce³⁺, Mn²⁺, YAlO₃:Ce³⁺, Y₃Al₅O₁₂:Ce³⁺, Y₃Al₅O₁₂:Cr³⁺, YAlO₃:Eu³⁺, Y₃Al₅O₁₂:Eu^{3r}, Y₄Al₂O₉:Eu³⁺, Y₃Al₅O₁₂:Mn⁴⁺, YAlO₃:Sm³⁺, YAlO₃:Tb³⁺, Y₃Al₅O₁₂:Tb³⁺, YAsO₄:Eu³⁺, YBO₃:Ce³⁺, YBO₃:Eu³⁺, YF₃:Er³⁺, Yb³⁺, YF₃:Mn²⁺, YF₃:Mn²⁺, Th⁴⁺, YF₃:Tm³⁺, Yb³⁺, (Y,Gd)BO₃:Eu, (Y,Gd)BO₃:Tb, (Y,Gd)₂O₃:Eu³⁺, Y_{1.34}Gd_{0.60}O₃(Eu,Pr), Y₂O₃:Bi³⁺, YOBr:Eu³⁺, Y₂O₃:Ce, Y₂O₃:Er³⁺, Y₂O₃:Eu³⁺, Y₂O₃:Ce³⁺, Tb³⁺, YOCl:Ce³⁺, YOCl:Eu³⁺, YOF:Eu³⁺, YOF:Tb³⁺, Y₂O₃:Ho³⁺, Y₂O₂S:Eu³⁺, Y₂O₂S:Pr³⁺, Y₂O₂S:Tb³⁺, Y₂O₃:Tb³⁺, YPO₄:Ce³⁺, YPO₄:Ce³⁺, Tb³⁺, YPO₄:Eu³⁺, YPO₄:Mn²⁺, Th⁴⁺, YPO₄:V⁵⁺, Y(P,V)O₄:Eu, Y₂SiO₅:Ce³⁺, YTaO₄, YTaO₄:Nb⁵⁺, YVO₄:Dy³⁺, YVO₄:Eu³⁺, ZnAl₂O₄:Mn²⁺, ZnB₂O₄:Mn²⁺, ZnBa₂S₃:Mn²⁺, (Zn,Be)₂SiO₄:Mn²⁺, Zn_{0.4}Cd_{0.6}S:Ag, Zn_{0.6}Cd_{0.4}S:Ag, (Zn,Cd)S:Ag, Cl, (Zn,Cd)S:Cu, ZnF₂:Mn²⁺, ZnGa₂O₄, ZnGa₂O₄:Mn²⁺, ZnGa₂S₄:Mn²⁺, Zn₂GeO₄:Mn²⁺, (Zn,Mg)F₂:Mn²⁺, ZnMg₂(PO₄)₂:Mn²⁺, (Zn,Mg)₃(PO₄)₂:Mn²⁺, ZnO:Al³⁺, Ga³⁺, ZnO:Bi³⁺, ZnO:Ga³⁺, ZnO:Ga, ZnO—CdO:Ga, ZnO:S, ZnO:Se, ZnO:Zn, ZnS:Ag⁺, Cl⁻, ZnS:Ag, Cu, Cl, ZnS:Ag, Ni, ZnS:Au, In, ZnS—CdS (25-75), ZnS—CdS (50-50), ZnS—CdS (75-25), ZnS—CdS:Ag, Br, Ni, ZnS—CdS:Ag⁺, Cl, ZnS—CdS:Cu, Br, ZnS—CdS:Cu, I, ZnS:Cl⁻, ZnS:Eu²⁺, ZnS:Cu, ZnS:Cu⁺, Al³⁺, ZnS:Cu⁺, Cl, ZnS:Cu, Sn, ZnS:Eu²⁺, ZnS:Mn²⁺, ZnS:Mn, Cu, ZnS:Mn²⁺, Te²⁺, ZnS:P, ZnS:P³⁻, Cl⁻, ZnS:Pb²⁺, ZnS:Pb²⁺, Cl⁻, ZnS:Pb, Cu, Zn₃(PO₄)₂:Mn²⁺, Zn₂SiO₄:Mn²⁺, Zn₂SiO₄:Mn²⁺, As⁵⁺, Zn₂SiO₄:Mn, Sb₂O₂, Zn₂SiO₄:Mn²⁺, P, Zn₂SiO₄:Ti⁴⁺, ZnS:Sn²⁺, ZnS:Sn, Ag, ZnS:Sn²⁺, Li⁺, ZnS:Te, Mn, ZnSZnTe:Mn²⁺, ZnSe:Cu⁺, Cl and ZnWO₄.

The compounds according to the invention here exhibit, in particular, advantages when mixed with further phosphors of other fluorescence colours or on use in LEDs together with phosphors of this type. The compounds according to the invention are preferably employed together with green-emitting phosphors. It has been found that, in particular on combination of the compounds according to the invention with green-emitting phosphors, optimisation of lighting parameters for white LEDs succeeds particularly well.

Corresponding green-emitting phosphors are known to the person skilled in the art or can be selected by the person skilled in the art from the list given above. Particularly suitable green-emitting phosphors here are (Sr,Ba)₂SiO₄:Eu, (Sr,Ba)₃SiO₅:Eu, (Sr,Ca)Si₂N₂O₂:Eu, BaSi₂N₂O₂:Eu, (Lu,Y)₃(Al,Ga,Sc)₅O₁₂:Ce, β-SiAlON:Eu, CaSc₂O₄:Ce, CaSc₂O₄:Ce,Mg, Ba₃Si₆O₁₂N₂:Eu and Ca₃(Sc,Mg)₂Si₃O₁₂:Ce. Particular preference is given to Ba₃Si₆O₁₂N₂:Eu and Ca₃(Sc,Mg)₂Si₃O₁₂:Ce.

In a further preferred embodiment of the invention, it is preferred to use the compound according to the invention as the sole phosphor. The compound according to the invention also exhibits very good results on use as the sole phosphor due to the broad emission spectrum with a high red content.

In still a further embodiment of the invention, it is preferred for the phosphors to be arranged on the primary light source in such a way that the red-emitting phosphor is essentially hit by the light from the primary light source, while the green-emitting phosphor is essentially hit by the light that has already passed through the red-emitting phosphor or has been scattered thereby. This can be achieved by installing the red-emitting phosphor between the primary light source and the green-emitting phosphor.

The phosphors or phosphor combinations according to the invention can be in the form of loose material, powder material, thick or thin layer material or self-supporting material, preferably in the form of a film. It may furthermore be embedded in an encapsulation material. The phosphors or phosphor combinations according to the invention here can either be dispersed in a resin (for example epoxy or silicone resin) as encapsulation material, or, in the case of suitable size ratios, arranged directly on the primary light source or alternatively arranged remote therefrom, depending on the application (the latter arrangement also includes “remote phosphor technology”). The advantages of remote phosphor technology are known to the person skilled in the art and are revealed, for example, by the following publication: Japanese Journal of Applied Physics Vol. 44, No. 21 (2005), L649-L651.

In a further embodiment, the optical coupling between the phosphor and the primary light source is preferably achieved by a light-conducting arrangement. This makes it possible for the primary light source to be installed at a central location and to be optically coupled to the phosphor by means of light-conducting devices, such as, for example, optical fibres. In this way, it is possible to achieve lamps adapted to the lighting wishes which merely consist of one or more different phosphors, which can be arranged to form a light screen, and an optical waveguide, which is coupled to the primary light source. In this way, it is possible to place a strong primary light source at a location which is favourable for electrical installation and to install lamps comprising phosphors which are coupled to the optical waveguides at any desired locations without further electrical cabling, but instead only by laying optical waveguides.

In addition, the phosphor according to the invention or the emission-converting material can be employed in a filament LED, as described, for example, in US 2014/0369036 A1.

The invention furthermore relates to a lighting unit, in particular for the backlighting of display devices, characterised in that it contains at least one light source according to the invention, and to a display device, in particular liquid-crystal display device (LC display), with backlighting, characterised in that it contains at least one lighting unit according to the invention.

The particle size of the phosphors according to the invention for use in LEDs is usually between 50 nm and 30 μm, preferably between 1 μm and 20 μm.

For use in LEDs, the phosphors can also be converted into any desired outer shapes, such as spherical particles, platelets and structured materials and ceramics. These shapes are in accordance with the invention summarised under the term “shaped bodies”. The shaped body is preferably a “phosphor body”. The present invention thus furthermore relates to a shaped body comprising the phosphors according to the invention. The production and use of corresponding shaped bodies are familiar to the person skilled in the art from numerous publications.

The compounds according to the invention have the following advantageous properties:
1) The compounds according to the invention have an emission spectrum having a high red content and they have a high photoluminescence quantum yield.
2) The compounds according to the invention have only low thermal quenching. Thus, the TQ_{1/2} values of the compounds according to the invention are usually in the region above 500 K.
3) The high temperature stability of the compounds according to the invention also enables the material to be used in light sources with high thermal loads.
4) Furthermore, the compounds according to the invention are distinguished by a long service life and facilitate high colour reproduction and high stability of the colour temperature in an LED. This enables warm-white pc-LEDs having high colour rendering indices at the same time as low colour temperatures (CCT<4000 K) to be achieved.
5) The compounds according to the invention can be prepared efficiently and inexpensively via a simple synthesis.

All embodiments described here can be combined with one another so long as the respective embodiments are not mutually exclusive. In particular, on the basis of the teaching of this specification, it is an obvious operation, as part of routine optimisation, precisely to combine various embodiments described here in order to arrive at a specific particularly preferred embodiment.

The following examples are intended to illustrate the present invention and show, in particular, the result of such illustrative combinations of the described embodiments of the invention. However, they should in no way be regarded as limiting, but instead are intended to prompt generalisation. All compounds or components which are used in the preparation are either known and commercially available or can be synthesised by known methods. The temperatures indicated in the examples are always in ° C. It furthermore goes without saying that, both in the description and also in the examples, the amounts of the constituents used in the compositions always add up to a total of 100%. Percent data should always be viewed in the given context.

### EXAMPLES

Measurement Methods

The phase formation of the samples was checked by means of X-ray diffractometry. For this purpose, the Rigaku Miniflex II X-ray diffractometer with Bragg-Brentano geometry was used. The radiation source used was an X-ray tube with Cu-Kα radiation (A=0.15418 nm). The tube was operated with a current strength of 15 mA and a voltage of 30 kV. The measurement was carried out in an angle range from 10 to 80° at 100°·min⁻¹.

The emission spectra were recorded using an Edinburgh Instruments Ltd. fluorescence spectrometer fitted with mirror optics for powder samples, at an excitation wavelength of 450 nm. The excitation source used was a 450 W Xe lamp. For temperature-dependent measurement of the emission, the spectrometer was fitted with an Oxford Instruments cryostat (MicrostatN2). The coolant employed was nitrogen.

Reflection spectra were determined using an Edinburgh Instruments Ltd. fluorescence spectrometer. For this purpose, the samples were placed and measured in a BaSO₄-coated Ulbricht sphere. Reflection spectra were recorded in a range from 250 to 800 nm. The white standard used was BaSO₄ (Alfa Aesar 99.998%). A 450 W Xe lamp was used as excitation source.

The excitation spectra were recorded using an Edinburgh Instruments Ltd. fluorescence spectrometer fitted with mirror optics for powder samples, at 550 nm. The excitation source used was a 450 W Xe lamp.

### Example 1: Preparation of NaAs_{0.995}Mn_{0.005}F_{5.995}

2.0 g of NaAsF₆ (9.4 mmol) and 0.05 g (0.2 mmol) of K₂MnF₆ are suspended in 5 ml of concentrated HF and stirred for about 2 h at 70° C. The crude product is subsequently filtered off with suction and washed a number of times with cold acetone until the material is acid-free. The pale-yellow powder obtained is dried in vacuo in a desiccator for 8 h. The CIE1931 colour point is at x=0.688 and y=0.312. The lumen equivalent is 231 lm/Wₒₚₜ.

### Example 2: Preparation of LiAs_{0.995}Mn_{0.005}F_{5.995}

2.0 g of LiAsF₆ (10.2 mmol) and 0.05 g (0.2 mmol) of K₂MnF₆ are suspended in 5 ml of concentrated HF and stirred for about 2 h at 70° C. The crude product is subsequently filtered off with suction and washed a number of times with cold acetone until the material is acid-free. The pale-yellow powder obtained is dried in vacuo in a desiccator for 8 h.

### Example 3: Preparation of KAs_{0.995}Mn_{0.005}F_{5.995}

2.0 g of KAsF₆ (8.8 mmol) and 0.05 g (0.2 mmol) of K₂MnF₆ are suspended in 5 ml of concentrated HF and stirred for about 2 h at 70° C. The crude product is subsequently filtered off with suction and washed a number of times with cold acetone until the material is acid-free. The pale-yellow powder obtained is dried in vacuo in a desiccator for 8 h.

### Example 4: Preparation of NaSb_{0.995}Mn_{0.005}F_{5.995}

2.0 g of NaSbF₆ (7.7 mmol) and 0.05 g (0.2 mmol) of K₂MnF₆ are suspended in 5 ml of concentrated HF and stirred for about 2 h at 70° C. The crude product is subsequently filtered off with suction and washed a number of times with cold acetone until the material is acid-free. The pale-yellow powder obtained is dried in vacuo in a desiccator for 8 h.

### Example 5: Preparation of LiSb_{0.995}Mn_{0.005}F_{5.995}

2.0 g of LiSbF₆ (8.2 mmol) and 0.05 g (0.2 mmol) of K₂MnF₆ are suspended in 5 ml of concentrated HF and stirred for about 2 h at 70° C. The crude product is subsequently filtered off with suction and washed a number of times with cold acetone until the material is acid-free. The pale-yellow powder obtained is dried in vacuo in a desiccator for 8 h.

### Example 6: Preparation of KSb_{0.995}Mn_{0.005}F_{5.995}

2.0 g of KSbF₆ (7.3 mmol) and 0.05 g (0.2 mmol) of K₂MnF₆ are suspended in 5 ml of concentrated HF and stirred for about 2 h at 70° C. The crude product is subsequently filtered off with suction and washed a number of times with cold acetone until the material is acid-free. The pale-yellow powder obtained is dried in vacuo in a desiccator for 8 h.

### Example 7: Production and Measurement of LEDs Using the Luminescent Materials

General procedure for the production and measurement of pc-LEDs: A mass mₚₕₒₛ (in g) of the luminescent material indicated in the respective LED example and a mass m_{YAG:Ce} (in g) (obtainable under the trade name U728 from Philips) are weighed out, m_{silicone} (in g) of an optically transparent silicone is added, and the components are subsequently mixed homogeneously in a planetary centrifugal mixer, so that the concentration of the luminescent material in the total mass is cₚₕₒₛ (in % by weight). The silicone/luminescent material mixture obtained in this way is applied to the chip of a blue semiconductor LED with the aid of an automatic dispenser and cured with supply of heat. The reference LED indicated in the present examples for the LED characterisation was filled with pure silicone without luminescent material. The blue semiconductor LEDs used have an emission wavelength of 450 nm and are operated with a current strength of 350 mA. The photometric characterisation of the LEDs is carried out using an Instrument Systems CAS 140 spectrometer and an ISP 250 integration sphere connected thereto. The LED is characterised by determination of the wavelength-dependent spectral power density. The resultant spectrum of the light emitted by the LED is used to calculate the colour point coordinates CIE x and y.

The sample weights of the luminescent materials and other materials used in the respective example and the colour coordinates of the LEDs obtained in accordance with the general procedure described above are summarised in Table 1. The associated LED spectra are depicted in FIG. 5.

TABLE 1
Composition and properties of LED A and LED B produced.

| | LED A (2700 K) | LED B (3000 K) |
|---|---|---|
| | with phosphor | with phosphor |
| Parameter | from Example 1: | from Example 1: |
| Mₚₕₒₛ/g | 8.43 | 6.84 |
| m_{YAG:Ce}/g | 0.71 | 0.71 |
| M_{silicone} | 4.46 | 4.41 |
| Cₚₕₒₛ /% by wt. | 62.0 | 57.2 |
| c_{YAG:Ce}/% by wt. | 5.22 | 5.94 |
| CIE 1931 x | 0.403 | 0.4338 |
| CIE 1931 y | 0.410 | 0.4578 |

### DESCRIPTION OF THE FIGURES

FIG. 1: X-ray powder diffraction pattern (Cu-K_{α} radiation) of NaAs_{0.995}Mn_{0.005}F_{5.995} (Example 1).

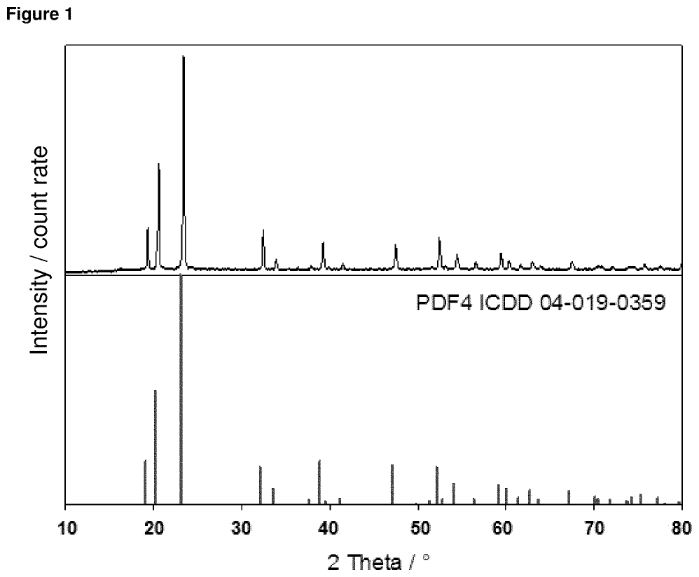

FIG. 2: Reflection spectrum of NaAs_{0.995}Mn_{0.005}F_{5.995} (Example 1).

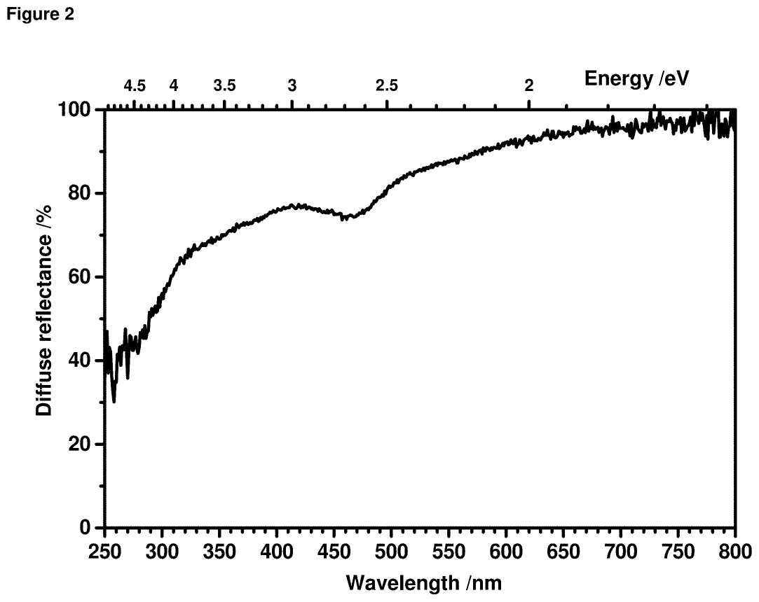

FIG. 3: Excitation spectrum of NaAs_{0.995}Mn_{0.005}F_{5.995} (Example 1) (λₑₘ=627 nm).

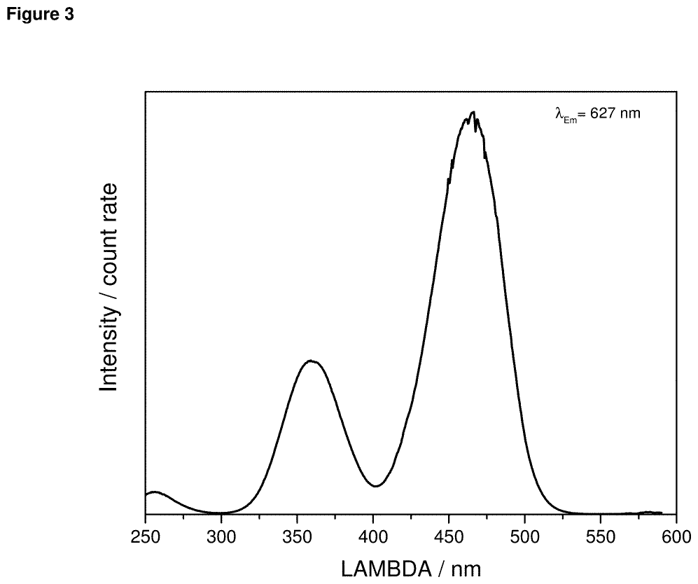

FIG. 4: Emission spectrum of NaAs_{0.995}Mn_{0.005}F_{5.995} (Example 1) (λₑₓ=465 nm).

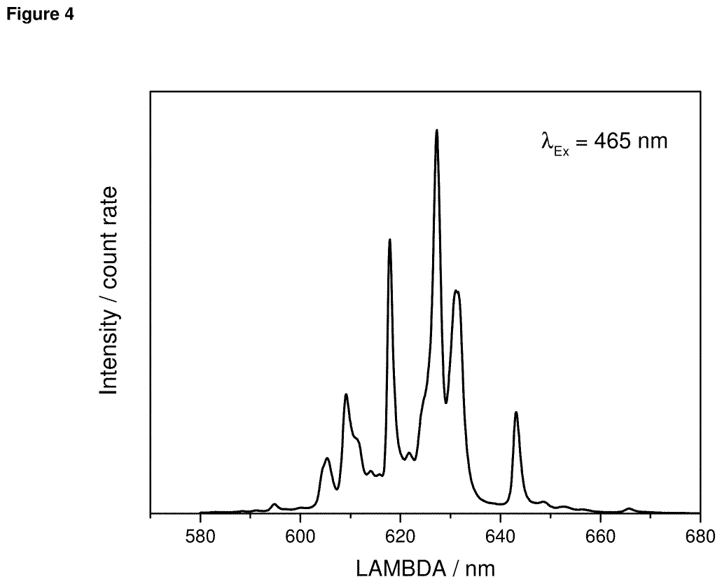

FIG. 5: Spectra of LED A and LED B comprising YAG:Ce and NaAsF₆:Mn⁴⁺ (Example 1) for the colour temperatures 2700 and 3000 K.

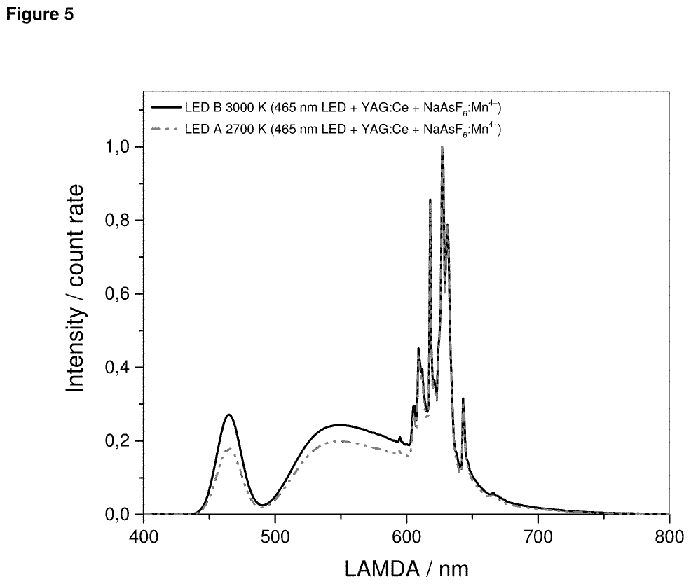

1. Compound of the general formula (I),
M¹M²₁₋ₓMnₓF₆₋ₓ (I)
where the following applies to the symbols and indices used:
M¹ is selected from the group consisting of Li, Na, K, Rb, Cs and mixtures of two, three or more thereof;
M² is selected from the group consisting of As, Sb, Bi and mixtures of two or three thereof; and
0<x<1.00.

2. Compound according to claim 1, characterised in that M¹ is selected from the group consisting of Li, Na, K and mixtures of two or three thereof.

3. Compound according to claim 1, characterised in that M² is selected from the group consisting of As, Sb and mixtures of As and Sb, which may optionally comprise Bi.

4. Compound according to claim 1, characterised in that 0<x≤0.80, preferably 0<x≤0.60, more preferably 0<x≤0.40, particularly preferably 0.001≤x≤0.20, especially preferably 0.001≤x≤0.10 and most preferably 0.001≤x≤0.010.

5. Compound according to claim 1, characterised in that the following applies to the symbols and indices used:
M¹ is selected from the group consisting of Li, Na, K and mixtures of two or three thereof;
M² is selected from the group consisting of As, Sb and mixtures of As and Sb, which may optionally comprise Bi; and
0<x≤0.60, preferably 0<x≤0.40, more preferably 0.001≤x≤0.20, particularly preferably 0.001≤x≤0.10 and most preferably 0.001≤x≤0.010.

6. Compound according to claim 1, characterised in that the compound is coated on the surface with another compound.

7. Process for the preparation of a compound according to claim 1, comprising the steps:
a) preparation of a suspension/solution comprising M¹, M² and Mn in an HF solution;
b) stirring the suspension/solution; and
c) separating off the solid obtained.

8. Process according to claim 7, in which step c) is followed by the following step:
d) washing and drying of the solid obtained.

9. A method for the partial or complete conversion of UV light, violet light and/or blue light into light having a longer wavelength, comprising achieving said conversion with a compound of claim 1 as a phosphor or conversion phosphor.

10. Emission-converting material comprising a compound according to claim 1 and optionally one or more further conversion phosphors.

11. Light source comprising at least one primary light source and at least one compound according to claim 1 or an emission-converting material comprising said at least one compound and optionally one or more further conversion phosphors.

12. Light source according to claim 11, where the primary light source comprises a luminescent indium aluminium gallium nitride.

13. Light source according to claim 12, where the luminescent indium aluminium gallium nitride is a compound of the formula InᵢGaⱼAlₖN, where 0≤i, 0≤j, 0≤k and i+j+k=1.

14. Lighting unit containing at least one light source according to claim 11.
